(19) United States
(12) Patent Application Publication
(10) Pub. No.: US 2024/0297481 A1
(43) Pub. Date: Sep. 5, 2024

(54) OPTOELECTRONIC COMPONENT, AND PROCESS FOR MANUFACTURING AN OPTOELECTRONIC COMPONENT

(71) Applicant: ams-OSRAM International GmbH, Regensburg (DE)

(72) Inventor: Hubert HALBRITTER, Dietfurt (DE)

(73) Assignee: ams-OSRAM International GmbH, Regensburg (DE)

(21) Appl. No.: 18/573,012

(22) PCT Filed: Jun. 10, 2022
(86) PCT No.: PCT/EP2022/065835

§ 371 Date: Dec. 21, 2023

(30) Foreign Application Priority Data
Jun. 29, 2021 (DE) 10 2021 116 674.8

(51) Int. Cl. H01S 5/11; H01S 5/02326; H01S 5/185

(52) U.S. Cl. CPC H01S 5/11; H01S 5/02326; H01S 5/185; H01S 2301/17; H01S 2301/18

(57) ABSTRACT

An optoelectronic component includes a housing. An optical element and a semiconductor laser are arranged along a common optical axis within the housing. The semiconductor laser is designed to generate, by means of a laser process, a light beam having a diffraction-limited divergence such that the light beam is substantially collimated on the optical element.

### CROSS-REFERENCE TO RELATED APPLICATIONS

The present application is a national stage entry from International Application No. PCT/EP2022/065835, filed on Jun. 10, 2022, published as International Publication No. WO 2022/274686 A1 on Jan. 5, 2023, and claims priority to German Patent Application No. 10 2021 116 674.8, filed Jun. 29, 2021, the disclosures of all of which are hereby incorporated by reference in their entireties.

### FIELD

The following description relates to an optoelectronic component and a process for manufacturing an optoelectronic component.

### BACKGROUND

Optical components and optical sensors find a variety of applications in the consumer sector or automotive. Light Detection and Ranging (LiDAR) is, for example, a key technology for mobile devices, such as cell phones, computers, tablets, and is also increasingly used in robots and vehicles, such as autonomous vehicles. However, today's LiDAR systems are often based on semiconductor lasers with low-quality, highly divergent and asymmetric beams, that require a high-precision integration of complicated lens systems for beam transformation. One such example is represented by “structured light” applications that use a surface emitter or VCSEL (vertical-cavity surface-emitting laser). Such systems today require a very complex optical setup, which in turn requires a certain height (see for example iPhone Face Recognition etc.).

“Structured light” applications based on edge emitting lasers are today limited to typically 200 mW output power, since single modes are usually required. For temperature-stabilized distributed feedback laser, DFB, only a few 10 mW are achievable. This is in contrast to the requirements of the applications, which require a corresponding power for large measuring distances. Many applications may require >>1 W (e.g. short pulse, longer range). With the common VCSEL lasers, this can currently only be realized by numerous apertures, complex optics and other measures. This implies correspondingly high costs for these optical devices and sensors. The mentioned points limit the performance, compactness, cost effectiveness and reliability of optical components and optical sensors, such as LiDAR systems.

It is a task of the presented description to propose an optoelectronic component and a process for manufacturing an optoelectronic component, which make the device more compact and cost effective.

These tasks are achieved by the subject matter of the independent claims. Further developments and embodiments are described in the dependent claims.

The following is based on the fact that any feature described with respect to any embodiment may be used alone or in combination with other features described in the following, and may also be used in combination with one or more features of any other embodiment or any combination of any other embodiment, unless described as an alternative. In addition, equivalents and modifications not described below may also be used without departing from the scope of the proposed optoelectronic component and process for manufacturing an optoelectronic component defined in the accompanying claims.

### SUMMARY

In the following, an improved concept in the field of optical devices, for example optical components and optical sensors, is presented. One aspect relates to the use of a semiconductor laser that generates highly collimated light due to its design. Surface-emitting laser diodes based on photonic crystals (PCSEL, or photonic-crystal surface-emitting laser) represent one example. A meta-optic or diffractive optic, such as a patterned platelet, can be used in this way, without the need for an additional collimating optic.

In at least one embodiment, an optoelectronic component comprises a housing. An optical element and a semiconductor laser are arranged along a common optical axis within the housing. The semiconductor laser is configured to generate a light beam with diffraction-limited divergence by a laser process. The light beam is substantially collimated at the optical element.

The optical element can, for example, comprise a diffractive optical element and/or a meta-optical element. A meta-optical element comprises at least one meta-surface, which in turn comprises an array of nanostructures, which are composed on a sub-wavelength scale and capable of replicating electromagnetic wavefronts.

The semiconductor laser can couple out a part of the radiation generated by the laser process in the direction of the optical element. Especially in modern semiconductor lasers with a large active area, the beam divergence becomes small. The out-coupled light beam is thus substantially collimated at the optical element. In this context, the term “substantially collimated” can be understood to mean that the beam divergence is so small, that the light beam is collimated for the use by the optical element.

The coupling can be done with a single high power mode of the semiconductor laser and allows the use of a simple diffractive optic or a meta-optic, because beam widening can be omitted for many applications. This also facilitates alignment, so that active elements on the side of a signal evaluation can be omitted. The optoelectronic device can thus be manufactured more compactly and at lower cost.

According to at least one embodiment, the semiconductor laser is free of collimating optics. In other words, due to the laser process or the optical properties of the laser a light beam with diffraction-limited divergence is generated, so that the light beam is substantially collimated at the optical element. Thus, the collimation is not performed by collimating optics in the semiconductor laser integrated in the laser for this purpose or located at a distance from the laser.

According to at least one embodiment, the semiconductor laser comprises an aperture. The semiconductor laser emits the light beam through the aperture. The beam divergence at half-width of the light beam is substantially smaller than 0.1° despite diffraction at the aperture.

The out-coupling of the laser radiation takes place via its aperture, which thus limits the active area. Due to diffraction at the aperture the beam divergence is influenced, but the divergence remains diffraction limited.

The value of approx. 0.1° can be achieved by an aperture diameter of 500 μm, for example. However, this depends on the semiconductor laser used.

In at least one embodiment, the semiconductor laser comprises a photonic crystal surface emitting semiconductor diode, PCSEL.

A surface-emitting photonic crystal laser usually comprises a two-dimensional photonic crystal structure that acts as lateral resonator. It comprises, for example, a thin layer of semiconductor material such as gallium arsenide=GaAs, gallium nitride=GaN, or indium phosphide=InP, which comprises a certain pattern (e.g. a square or triangular pattern) of holes extending over a certain area. The semiconductor material is transparent or non-absorbing to the generated laser radiation.

The laser process or laser amplification takes place by stimulated emission and is achieved by coupling the photonic crystal structure with a thin active layer (amplifier layer) below the photonic crystal layer within evanescent waves of the laser modes. The active region is separated from the photonic crystal structure only by a thin electron barrier layer, to confine the electric charge carriers in the active region. Above and below this structure an optically transparent and electrically conductive cladding layer of doped semiconductor is located.

An electric current to pump the active region is applied via metallic electrodes on the top and bottom sides. On the laser emission side (top side), this electrode covers only a small part of the area, e.g. a rectangular area with dimensions in the order of 10 μm to 100 μm. It is also possible to use a top electrode with a rectangular region removed from the center. This results in pumping of the photonic crystal mode in its outer region, while an output coupling is possible in the central region.

Another aspect is that the photonic crystal structure also diffracts a portion of the light, so that the light beam is created and can be coupled out. This output beam leaves the semiconductor laser in a direction perpendicular to an output surface. Especially for semiconductor lasers with a large active area, the beam divergence becomes small. The laser effectively emits a collimated light beam that does not require a collimating lens.

Due to their design, PCSELs can generate single modes with high output powers of >500 mW up to 30 W (in pulse mode). Thereby, these lasers are particularly interesting for LiDAR and other distance measurement techniques such as time-of-flight, because they enable the measurement of large distances of several 10 m. Furthermore, these lasers show no or little beam widening, so that collimation can be omitted. In addition, the PCSEL wavelength stability is comparable to other surface-emitting lasers, such as the VCSEL.

According to at least one embodiment, the optical element is arranged to pattern the light beam emitted by the semiconductor laser such that a known pattern is projectable onto an external object.

Due to the so structured optical element, structured light can be generated. Structured light is to be understood as the process of projecting a known pattern (for example, as grids or horizontal bars) onto an external object. The way the pattern deforms when it impinges on surfaces allows image processing systems to compute the depth and surface information of the objects in the scene to generate a 3D image. In LiDAR or ToF (time-of-flight) applications, light travel times of individual structures of the pattern can be measured to obtain distance information as well. For example, a point grid is generated by the structured optical element for such applications.

According to at least one embodiment, the optical element comprises a non-zero distance from the semiconductor laser. The optical element can be arranged at a distance, albeit small, from the semiconductor laser.

According to at least one embodiment, the optical element is mounted directly on the semiconductor laser. The optical element can be arranged at an effective distance of zero from the semiconductor laser. For example, the optical element is attached or mounted to a surface, such as the aperture.

According to at least one embodiment, the optical element is integrated in the semiconductor laser. In this way, there is no distance to the semiconductor laser. Furthermore, it is possible to manufacture the optical element together with the laser in a common process, for example with CMOS technology on a wafer. This allows further cost savings.

According to at least one embodiment, the optical component further comprises a widening optic and a recollimation optic.

Depending on the output power of the semiconductor laser, it can be necessary or useful to use widening optics and recollimation optics. For example, low output power also means a smaller aperture or active area. Due to diffraction at the smaller aperture, beam divergence increases. This increased beam divergence can be compensated by the widening optic, which widens the output light beam. This causes the light beam to initially lose collimation. Collimation at the optical element is then restored by the downstream recollimation optic.

According to at least one embodiment, the widening optic is integrated in the semiconductor laser. For example, the widening optic can be integrated on or in a surface of the semiconductor laser or be designed as a flat platelet. In addition, it is possible to manufacture the widening optic together with the laser in a common process, for example with CMOS technology on a wafer. This allows further cost savings.

According to at least one embodiment, the widening optic is mounted on the semiconductor laser. For example, the widening optics is attached or mounted to a surface, such as the aperture.

According to at least one embodiment, the recollimation optic is integrated in the optical element.

According to at least one embodiment, the recollimation optic is integrated on a front side or a rear side of the optical element and mounted on the semiconductor laser. In this way, the distance of the recollimation optic to the semiconductor laser can also be zero.

According to at least one embodiment, the optical element and the semiconductor laser are arranged in a first chamber within the housing. The housing further comprises a second chamber in which an optical detector is arranged. In this way, a low-cost module can be manufactured in which emission and detection are arranged directly adjacent to each other and thus compact.

According to at least one embodiment, a height of the housing is substantially determined by the distance between the optical element and the semiconductor laser. In a sense, the optical element represents the output side of the optoelectronic element. The distance to the semiconductor laser can be kept small according to the presented improved concept, so that a low height of the housing becomes possible.

One embodiment of a process for manufacturing an optoelectronic component comprises the following steps. First, a housing is provided. An optical element and a semiconductor laser are arranged in the housing along a common optical axis. Thereby, the semiconductor laser is configured to generate a light beam with diffraction-limited divergence by a laser process such that the light beam is substantially collimated at the optical element.

The following description of the figures of exemplary embodiments serves to further illustrate and explain aspects of the improved concept. Components and parts with the same structure or the same effect appear with corresponding reference signs. Insofar as components and parts in different figures correspond in function, their description is not necessarily repeated for each of the following figures.

### BRIEF DESCRIPTION OF THE DRAWINGS

It shows:

FIG. 1 an exemplary embodiment of an optoelectronic element,

FIG. 2 a further exemplary embodiment of an optoelectronic element, and

FIG. 3 a further exemplary embodiment of an optoelectronic element.

### DETAILED DESCRIPTION

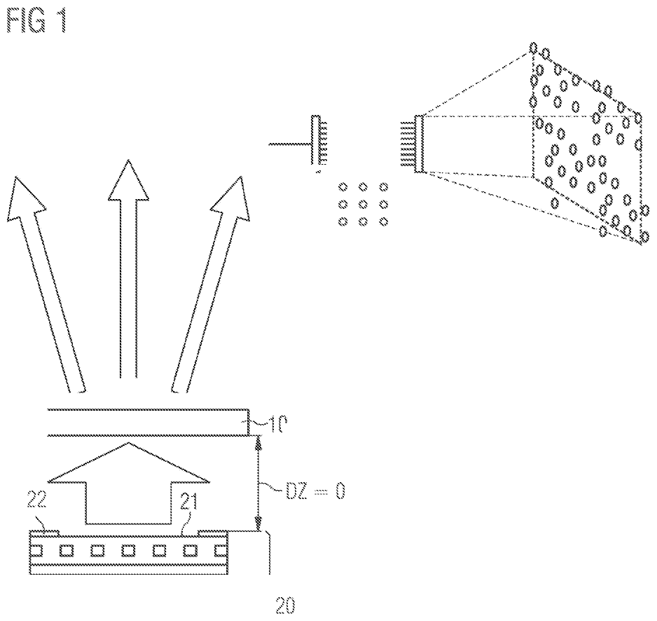

FIG. 1 shows an exemplary embodiment of an optoelectronic component. The optoelectronic component comprises a housing, a diffractive optical element 10 and a semiconductor laser 20. The diffractive optical element and the semiconductor laser are arranged in the housing, the housing itself not being shown in the drawing. The semiconductor laser and the diffractive optical element are arranged along a common optical axis.

The diffractive optical element 20 is designed for the projection of structured light, for example for a LiDAR or ToF application. The optics comprises, for example, a single platelet or multiple stacked platelets. These platelets are, for example, grid-shaped so that they can image or project a regular dot pattern onto an external object (see right upper part of the drawing).

In this embodiment, the diffractive optical element is arranged at a distance DZ from an active area 21 of the semiconductor laser 20. The semiconductor laser comprises a surface-emitting photonic crystal laser, PCSEL. This type of semiconductor laser comprises an aperture 22 at the active area (i.e. the surface facing the diffractive optics) by means of which light beams can be coupled out of the laser. In operation, the semiconductor laser generates a light beam with diffraction-limited divergence by a laser process. Thereby, the beam divergence at half-width of the light beam is substantially less than 0.1° despite diffraction at the aperture, depending on a diameter of the aperture. Furthermore, the semiconductor laser is free of collimating optics. In this exemplary embodiment, no further optics are integrated into the semiconductor laser itself or arranged along the common optical axis.

The distance between the active area 21 of the semiconductor laser 20 and the diffractive optical element 10 substantially determines a housing height. Since the out-coupled laser light is substantially collimated at the diffractive optical element, this distance and thus the housing height can be kept small. In addition to this advantageously small height, no active alignment of the optical elements with respect to each other, for example by signal processing components of the optoelectronic element or a downstream signal processing, is necessary. A passive alignment during the manufacturing of the optoelectronic element is usually sufficient with good accuracy.

Typical parameters for the PCSEL laser are as follows:
Circular aperture>200 μm
Output power: typ. 500 mW (CW) to 10 W (pulsed))
low M²
typ. at 500 μm apertures
˜<0.1° 1/e² divergence
Wavelength stability
˜0.07 nm/K—comparable to VCSEL

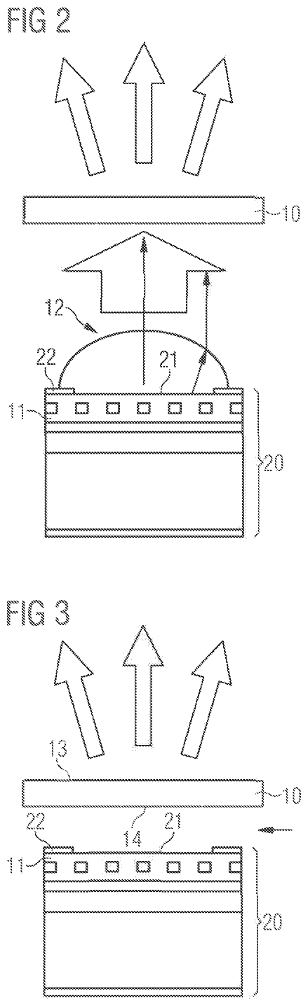

FIG. 2 shows a further exemplary embodiment of an optoelectronic element. The arrangement of the components corresponds substantially to the arrangement already shown in FIG. 1. For an improved collimation to values much smaller than 0.1° or for the use of semiconductor lasers with lower powers, a recollimation optic and a widening optic are also provided.

At lower output power, for example, the semiconductor laser comprises a smaller aperture 22 or a smaller active area. Due to the smaller aperture, there is a higher beam divergence due to diffraction. In the exemplary embodiment shown, a diffractive widening optics 11 is therefore integrated in a surface or on a surface of the semiconductor laser 20. This can be implemented, for example, as a flat platelet or as a regular lens during a manufacturing process of the semiconductor laser. For example, during epitaxy, additional layers at specific intervals or diffractive elements can be introduced into the material. Another possibility are so-called Fresnel lenses.

The widening optic 11 has the effect of widening the out-coupled light beam and, thus, reducing the divergence. As a rule, the recollimation optic 12 is then arranged downstream of the widening optic 11 and also along the optical axis. In this example, the recollimation optic is arranged on the surface 21 of the semiconductor laser, for example on the aperture 22. By means of the recollimation optic, the collimation of the out-coupled light beam is then restored, so that collimated light is at the diffractive optical element.

FIG. 3 shows a further exemplary embodiment of an optoelectronic element. This arrangement is also similar to the one shown so far. It can be used, for example, for lower output powers and improved collimation. In this example, the widening optic 11 is integrated into a chip surface 21, for example as a flat platelet, in the semiconductor material. The recollimation optic 12, on the other hand, is integrated either on a front side 13 or on a rear side 14 of the diffractive optical element 10. Alternatively, the widening optic can also be integrated in the diffractive optical element, for example in its rear side, i.e. the side facing the semiconductor laser. In such an embodiment, the distance between diffractive optical element and semiconductor laser can be minimized up to zero.

The foregoing description explains many features in specific detail. These are not intended to be construed as limitations on the scope of the improved concept or what may be claimed, but rather as exemplary descriptions of features specific only to certain embodiments of the improved concept. Certain features described in this description in connection with individual embodiments can also be implemented in combination in a single embodiment. Conversely, various features described in connection with a single embodiment may also be implemented in multiple embodiments separately or in any suitable sub-combination. In addition, although features are described above as working together in certain combinations and are even originally claimed as such, one or more features may be excluded from a claimed combination in some instances, and the claimed combination can be directed to a sub-combination or variation of a sub-combination.

Although operations are shown in a particular order in the drawings, this is not to be understood to mean that these operations must be performed in the order shown or in sequential order, or that all operations shown must be performed to achieve the desired results. In certain circumstances, deviating sequences or parallel processing can be advantageous.

A number of implementations have been described. Nevertheless, various modifications can be made without departing from the spirit and scope of the improved concept. Accordingly, other implementations also fall within the scope of the claims. For example, the diffractive optical element can be replaced or supplemented by a meta-optical element in the embodiments presented.

1. An optoelectronic component, comprising:
a housing,
an optical element and a semiconductor laser, arranged along a common optical axis within the housing,
a widening optic and a recollimation optic, wherein:
the semiconductor laser is configured to generate a light beam with diffraction-limited divergence by a laser process, so that the light beam is substantially collimated at the optical element.

2. The optoelectronic component according to claim 1, wherein the semiconductor laser is free of collimating optics.

3. The optoelectronic component according to claim 1, wherein
the semiconductor laser comprises an aperture, through which the light beam of the semiconductor layer is emitted, and
the beam divergence at half-width of the light beam is substantially less than 0.1° despite diffraction at the aperture.

4. The optoelectronic component according to claim 1, wherein the semiconductor laser comprises a photonic crystal surface emitting semiconductor diode, PCSEL.

5. The optoelectronic component according to claim 1, wherein the optical element is configured to pattern the light beam emitted by the semiconductor laser such that a known pattern is projectable onto an external object.

6. The optoelectronic component according to claim 1, wherein the optical element comprises a non-zero distance from the semiconductor laser, or wherein the optical element is mounted directly on the semiconductor laser.

7. The optoelectronic component according to claim 1, wherein the optical element is integrated in the semiconductor laser.

8. (canceled)

9. The optoelectronic component according to claim 1, wherein the widening optic is integrated in the semiconductor laser.

10. The optoelectronic component according to claim 1, wherein the widening optic is mounted on the semiconductor laser.

11. The optoelectronic component according to claim 1, wherein the recollimation optic is integrated in the optical element.

12. The optoelectronic component according to claim 11, wherein the recollimation optic is integrated on a front side or a rear side of the optical element and mounted on the semiconductor laser.

13. The optoelectronic component according to claim 1, wherein
the optical element and the semiconductor laser are arranged in a first chamber within the housing, and
the housing comprises a second chamber, in which an optical detector is arranged.

14. The optoelectronic component according to claim 1, wherein a height of the housing is substantially determined by the distance between the optical element and the semiconductor laser.

15. A process for manufacturing an optoelectronic component, comprising:
providing a housing, and
arranging an optical element and a semiconductor laser in the housing along a common optical axis, wherein:
the semiconductor laser is configured to generate a light beam with diffraction-limited divergence by a laser process, so that the light beam is substantially collimated at the optical element, and
the optoelectronic component comprises a widening optic and a recollimation optic.

16. (canceled)

17. The process according to claim 15, wherein the widening optic is manufactured in a common process with the semiconductor laser.

18. The optoelectronic component according to claim 1, wherein the recollimation optic is arranged downstream of the widening optic in the light beam.
